(19) United States
(12) Patent Application Publication
(10) Pub. No.: US 2007/0224729 A1
(43) Pub. Date: Sep. 27, 2007

(54) Method for manufacturing a flip-chip package, substrate for manufacturing and flip-chip assembly

(76) Inventors: Martin Reiss, Dresden (DE); Bernd Scheibe, Dresden (DE); Stephan Blaszczak, Freyburg (DE)

Correspondence Address: SLATER & MATSIL LLP, 17950 PRESTON ROAD, SUITE 1000, DALLAS, TX, 75252, US

(21) Appl. No.: 11/386,072

(22) Filed: Mar. 21, 2006

(51) Int. Cl. H01L 21/00

(52) U.S. Cl. 438/106

(57) ABSTRACT

A method for manufacturing a flip-chip package, in particular to a method for filling the space between an active side of a chip and a contact side of a substrate is disclosed. Furthermore, a substrate for supporting the filling and a flip-chip assembly is disclosed. The substrate includes a feed opening extending from the chip mounting surface within the chip supporting area to the substrate mounting surface. Via this feed opening, the underfill material is filled into the intervening space between substrate and chip.

### TECHNICAL FIELD

The invention generally relates to a method for manufacturing a flip-chip package and in particular for filling the space between an active side of a chip and a contact side of a substrate. Furthermore, the invention relates to a substrate for supporting the filling and a flip-chip assembly.

### BACKGROUND

In this description the word “chip” is used for both the chip within the wafer formation and for the die, i.e., the chip after singularizing it from the wafer by a dicing process.

There are many methods known for filling the space between an active side of a chip and a contact side of a substrate. One method is known as “Non Flow” underfill technology. In this method, an underfill material is applied onto the contact surface of the substrate before attaching the chip, i.e., the space is filled by “non flow” of the underfill material. One of the disadvantages of this method is the necessity of exactly dimensioning the amount of underfill material. Otherwise the space is overfilled or on the other hand the space is not filled completely.

Another method is known as “Capillary”-Underfill. In this method, an underfill material is dispensed alongside the chip after attaching the die onto the substrate. Thereafter the space between the active side of the chip and the contact side of the substrate is filled by capillary effect. For this method an expensive material is needed with a fluidity suitable for the capillary effect and is not yet applicable on large-scale (“high volume”) production.

A third known method is to fill the space between the active side of the chip and the contact side of the substrate with a mold compound before or while molding an encapsulation or housing around the flip-chip package. This method is called “Undermolding.” Due to the minor height of the space to be underfilled, the mold compound must be provided with a proper fluidity. Generally this is accomplished by adding a very expensive filler material to the mold compound. On the other hand more than 50% of the mold material is cull, i.e., it is discarded by cutting to the size of the semiconductor device or is left in the runner.

### SUMMARY OF THE INVENTION

In one aspect, the invention facilitates the process of underfilling the chip mounted on a substrate.

In another aspect, the invention avoids the necessity of a low viscosity of the underfill material thereby avoiding the usage of expensive filler materials or the like.

In a further aspect, the invention ensures a complete underfilling and to prevent inclusions of air.

Embodiments of the invention relate to a substrate for manufacturing a flip-chip assembly. This substrate comprises a conductive wiring formed therein or thereon, a chip mounting surface with a chip supporting area, a substrate mounting surface opposite to the chip mounting surface, a plurality of first contact pads for substrate-to-chip contacts arranged on the chip mounting surface within the chip supporting area and a plurality of second contact pads for substrate-to-outside contacts arranged on the substrate mounting surface. The first contact pads are at least partially connected with the second contact pads by the conductive wiring of the substrate. A feature of the substrate is a feed opening extending from the chip mounting surface within the chip supporting area to the substrate mounting surface.

The feed opening allows the filling, dispensing or printing of the underfill material after the chip is mounted. It also allows for the underfill material to be supplied from the substrate mounting surface.

In one embodiment of the invention, a substrate is provided with a plurality of feed openings. The feed openings should be arranged in such a pattern that the even flow of the underfill material is supported.

In a further refinement the feed opening is rectangular in cross section. Moreover, it is advantageous that the cross section of the feed opening is similar to the active side of the chip. Thereby the distances for the flow of the underfill material from the feed opening to the border of the chip are reduced.

Embodiments of the invention also relate to a flip-chip assembly. This flip-chip assembly comprises a substrate, a chip and underfill material.

The substrate comprises a conductive wiring formed therein or thereon, a chip mounting surface with a chip supporting area, a substrate mounting surface opposite to the chip mounting surface, a plurality of first contact pads for substrate-to-chip contacts arranged on the chip mounting surface within the chip supporting area and a plurality of second contact pads for substrate-to-outside contacts arranged on the substrate mounting surface. The first contact pads are at least partially connected with the second contact pads by the conductive wiring of the substrate. The substrate is further provided with a feed opening extending from the chip mounting surface within the chip supporting area to the substrate mounting surface.

The chip has an active side provided with chip contacts. The chip is mounted with the active side facing the chip mounting surface within the chip supporting area with a distance between the active side and the chip mounting surface forming an intervening space. The distance is defined by contact bumps interconnecting the chip contacts and the first contacts.

The underfill material is filling the complete intervening space and the feed opening.

This assembly is provided not only with a mechanical connection on the surfaces of the chip supporting area and the active side but also is positively connected in the feed opening. Thereby the underfill material is able to absorb forces in horizontal directions.

In one embodiment of the invention the intervening space is filled with mold compound. This avoids the usage of expensive underfill material.

The package can be accomplished as “bare backside” type, wherein the side walls and the backside of the chip are not covered by any encapsulation. Otherwise, additionally to the filling of the intervening space the chip can be completely enveloped by the mold compound.

The invention also relates to a method for manufacturing a flip-chip package. The method comprises providing a substrate with the features as mentioned above, providing a chip with the features mentioned above, mounting the chip on the substrate and filling the intervening space.

In a refinement the underfill material is cured after the filling process. Therefore, the assembly can be exposed to a temperature of about 180° C. if the underfill material is heat curable.

In a further refinement a pressure is applied to the underfill material during the filling process. Thereby the process becomes independent from the viscosity of the underfill material. This can be advantageously applied in a further refinement wherein a liquid mold compound is filled into the feed opening as underfill material. The liquid mold compound is cured by heat exposure after filling as explained above.

In a further refinement the chip is enveloped completely by mold compound.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows a cross-section through a substrate;

FIG. 2 shows a cross-section through a chip;

FIG. 3 illustrates a cross-section of a chip mounted on a substrate;

FIG. 4 illustrates a cross-section of a flip-chip assembly with bare backside;

FIG. 5 illustrates a cross-section of a flip-chip assembly with a completely molded encapsulation;

FIGS. 6a-6e, collectively referred to as FIG. 6, shows an inventive two-step method for underfilling and making an encapsulation;

FIG. 7 shows a front view of a substrate with a feed opening and feeding grooves; and

FIG. 8 shows several configurations of grooves in cross-section view.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

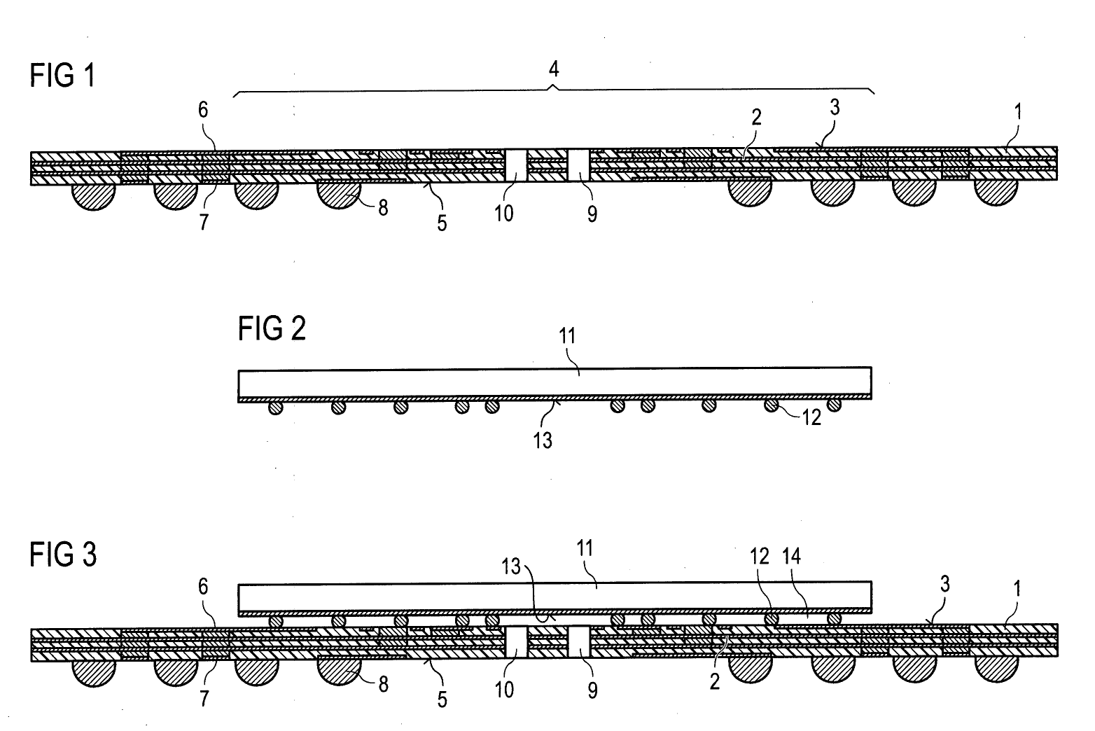

As shown in FIG. 1 a substrate 1 is provided with a conductive wiring 2 formed therein. The substrate 1 has a chip mounting surface 3 with a chip supporting area 4. The substrate 1 has a substrate mounting surface 5 opposite to the chip mounting surface 3.

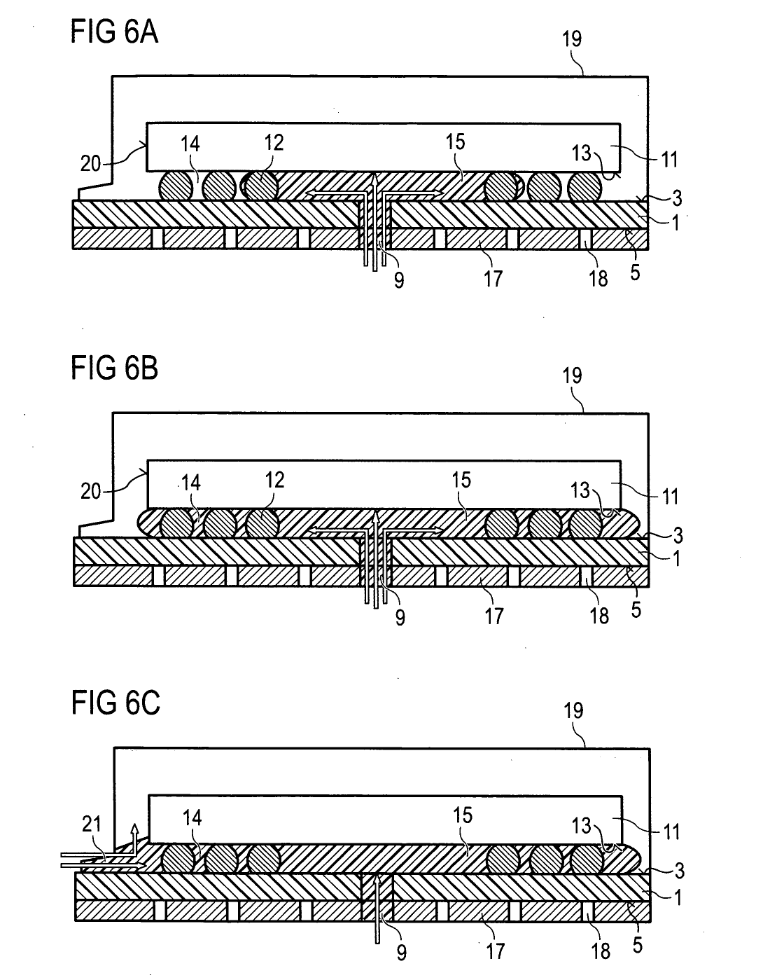

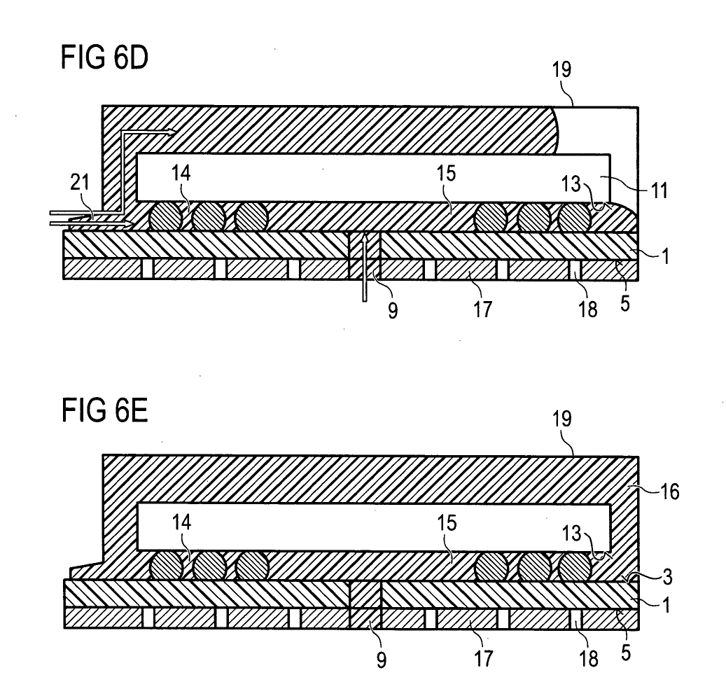

The conductive wiring 2 is connected with first pads 6 on the chip mounting surface 3 and also with second pads 7 on the substrate mounting surface 5. In this example the second pads are provided with solder balls 8 for subsequently mounting the substrate 1 on a printed circuit board (not shown) or other assembly. The solder balls 8 can be arranged on the substrate 1 before any further chip mounting processes as shown in FIG. 1 as well as after chip mounting processes as is described later and shown in FIG. 6.

Two feed openings 9, 10 are arranged in the center of the chip supporting area 4. These openings 9, 10 extend from the chip mounting surface 3 to the substrate mounting area 5.

As shown in FIG. 2, a chip 11 is provided with bumps 12 for mounting the chip 11 onto the substrate 1 within the chip supporting area 4 of the chip mounting surface 3. The bumps 12 may be comprised of solder bumps and mounting is performed by a reflow process. In another embodiment, the bumps 12 may be comprised of adhesive material and the chip 11 is mounted and contacted by curing the adhesive material. The bumps 12 are applied on an active side 13 of the chip 11 where contact pads (not shown) are arranged, when the chip 11 is still within the wafer formation.

After dicing the chip 11 is “flipped,” i.e., it is turned with its active side face to the chip mounting surface 3. The bumps 12 are contacting the first pads 6 as shown in FIG. 3. Thereafter the chip 11 is fixed by reflow or curing the bumps 12 depending on the bump material.

The bumps 12 define a distance between the chip mounting surface 3 and the active side 13. This distance causes an intervening space 14 bounded by these surfaces 3 and 13.

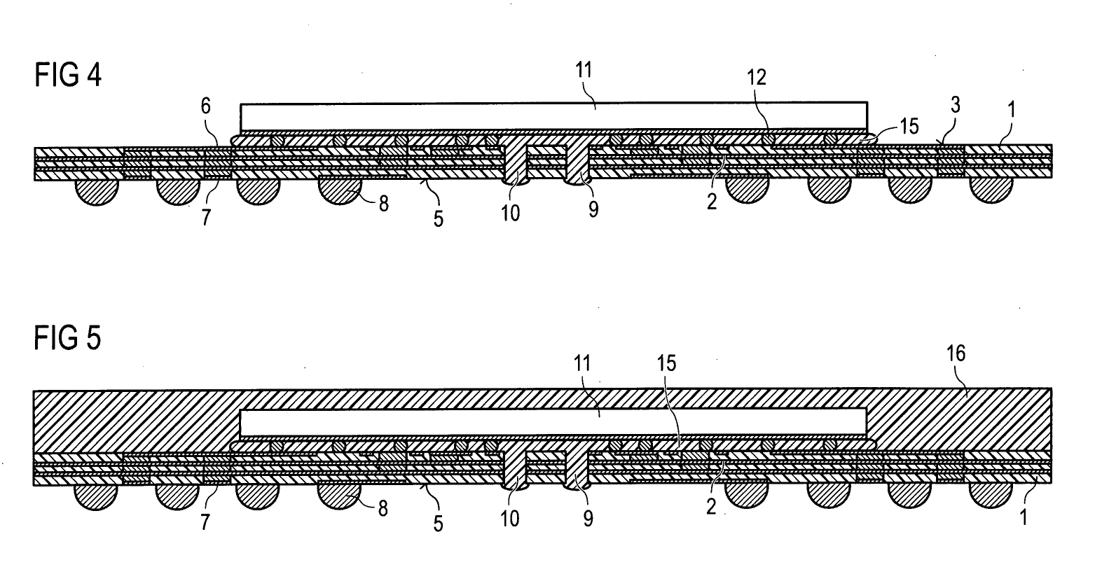

After mounting the chip 11, underfill material 15 flows via the feed openings 9, 10 within intervening space 14 to the border of the chip 11. This is shown in FIG. 4. A variety of known materials can be used as underfill material 15. In case an underfill material based on the capillary effect is used, the underfill material can be applied into the feed opening 9, 10 by simple dispensing. More advantageously, mold compound can be used as underfill material 15. In this case, the underfill material 15 is pressed into the intervening space 14 via feed openings 9, 10.

The status in FIG. 4 is sufficient for a “bare backside”-flip-chip package. But it is also possible to finish the flip-chip package with an encapsulation 16 as shown in FIG. 5.

The procedure of making an encapsulated flip-chip package is shown in more detail in FIGS. 6a-6e, collected referred to as FIG. 6. As shown in FIG. 6 the substrate is supported by a vacuum chuck 17 during the entire process. This vacuum chuck 17 is provided with vacuum feedthroughs 18 that are in turn connected to a vacuum source (not shown). By means of a vacuum the substrate 1 is hold on the vacuum chuck 17.

As shown in FIG. 6a, a mold 19 is disposed on the substrate 1 covering the chip 11. Then mold compound as underfill material is pressed via the feed opening 9 into the intervening space 14. Feed opening 9 acts as a first mold gate. As shown in FIG. 6b, the filling continues until the border 20 of the chip 11 is reached. After that a second mold gate 21 is opened and mold compound for establishing the encapsulation 16 is pressed into the mold 19. When mold compound is pressed into the mold 19 via the second mold gate 21 material supply via feed opening 9 is stopped. Only the pressure in the feed opening 9 is hold to avoid any reverse flow of mold compound back to the feed opening 9. This is shown in FIGS. 6c and 6d.

When the mold 19 is filled completely the pressure is switched off and after cooling the mold compound the encapsulation process is complete. The final structure is shown in FIG. 6e.

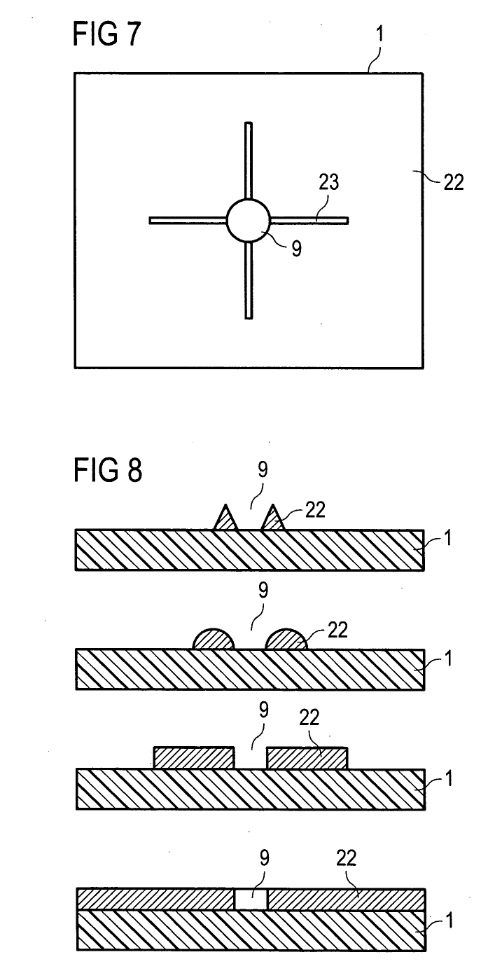

As shown in FIGS. 7 and 8, the substrate 1 is provided with a layer of solder resist 22. It is not necessary to use solder resist but it is a preferred material because its usage is very common. The layer of solder resist is patterned by forming grooves 23 therein. These grooves 23 promote the flow of the underfill material. FIG. 8 shows several embodiments of the layer of solder resist 22 to form the grooves.

As shown in FIG. 7 the grooves 23 are directed radially outwards from the feed opening 9.

Although the present invention and its advantages have been described in detail, it should be understood that various changes, substitutions and alterations can be made herein without departing from the spirit and scope of the invention as defined by the appended claims.

What is claimed is:

1. A substrate for manufacturing a flip-chip assembly, the substrate comprising:
a conductive wiring formed therein or thereon;
a chip mounting surface with a chip supporting area;
a substrate mounting surface opposite to the chip mounting surface;
a plurality of first contact pads for substrate-to-chip contacts arranged on the chip mounting surface within the chip supporting area;
a plurality of second contact pads for substrate-to-outside contacts arranged on the substrate mounting surface, wherein the plurality of first contact pads are at least partially connected with the plurality of second contact pads by the conductive wiring of the substrate; and
a feed opening extending from the chip mounting surface to the substrate mounting surface within the chip supporting area.

2. The substrate according to claim 1, wherein the substrate includes a plurality of feed openings.

3. The substrate according to claim 1, wherein the plurality of feed openings are rectangular in cross section.

4. The substrate according to claim 3, wherein the cross section of the plurality of feed openings are similar to an active side of a chip.

5. The substrate according to claim 1, wherein the plurality of feed openings are arranged in the center of the chip supporting area.

6. The substrate according to claim 1, wherein grooves are provided in the chip mounting surface, each groove being connected at one end with the plurality of feed openings.

7. The substrate according to claim 6, wherein the grooves extend radially outwards from the plurality of feed openings.

8. The substrate according to claim 1, wherein the grooves are arranged within a layer of solder resist.

9. A flip-chip assembly comprising:
a substrate, comprising:
a conductive wiring formed therein or thereon;
a chip mounting surface with a chip supporting area;
a substrate mounting surface opposite to the chip mounting surface;
a plurality of first contact pads for substrate-to-chip contacts arranged on the chip mounting surface within the chip supporting area;
a plurality of second contact pads for substrate-to-outside contacts arranged on the substrate mounting surface, wherein the plurality of first contact pads are at least partially connected with the plurality of second contact pads by the conductive wiring of the substrate; and
a feed opening extending from the chip mounting surface within the chip supporting area to the substrate mounting surface;
a chip having an active side provided with chip contacts, the chip being mounted with the active side facing the chip mounting surface within the chip supporting area with a distance between the active side and the chip mounting surface forming an intervening space, wherein the distance is determined by contact bumps interconnecting the chip contacts and the first contacts; and
an underfill material filling the complete intervening space and the feed opening.

10. The flip-chip assembly according to claim 9, wherein the intervening space is filled with mold compound.

11. The flip-chip assembly according to claim 10, wherein the chip is completely enveloped by the mold compound.

12. The flip-chip assembly according to claim 9, wherein the substrate includes a plurality of feed openings.

13. The flip-chip assembly according to claim 9, wherein the plurality of feed openings are rectangular in cross section.

14. The flip-chip assembly according to claim 9, wherein grooves are provided in the chip mounting surface, each groove being connected at one end with the plurality of feed openings.

15. A method for manufacturing a flip-chip package, the method comprising:
providing a substrate that includes:
a conductive wiring formed therein or thereon;
a chip mounting surface with a chip supporting area;
a substrate mounting surface opposite to the chip mounting surface;
a plurality of first contact pads for substrate-to-chip contacts arranged on the chip mounting surface within the chip supporting area;
a plurality of second contact pads for substrate-to-outside contacts arranged on the substrate mounting surface, wherein the plurality of first contact pads are at least partially connected to the plurality of second contact pads by the conductive wiring of the substrate; and
a feed opening extending from the chip mounting surface within the chip supporting area to the substrate mounting surface;
providing a chip having an active side provided with chip contacts;
mounting the chip with the active side face to the chip mounting surface within the chip supporting area with a distance between the active side and the chip mounting surface forming an intervening space wherein the distance is defined by contact bumps interconnecting the chip contacts and the plurality of first contacts; and
filling an underfill material into the feed opening thereby filling the complete intervening space and the feed opening.

16. The method of claim 15, wherein the underfill material is cured after filling.

17. The method of claim 15, wherein a pressure is applied to the underfill material during the filling process.

18. The method of claim 17, wherein a liquid mold compound is filled into the feed opening as an underfill material.

19. The method of claim 15, wherein the chip is enveloped completely by the mold compound.

20. The method of claim 15, wherein the substrate is placed onto a vacuum chuck with the bare substrate mounting surface thereof engaging the vacuum chuck, and the substrate is supported by the vacuum chuck during the underfill process and solder balls are applied on the substrate mounting surface after underfilling.
